(19) United States
(12) Patent Application Publication
(10) Pub. No.: US 2009/0095176 A1
(43) Pub. Date: Apr. 16, 2009

(54) Method and apparatus for PCB finishing processes

(75) Inventors: Albert Yafe, Raanana (IL); Amir Noy, Herzlia (IL)

Correspondence Address: Pearl Cohen Zedek Latzer, LLP, 1500 Broadway, 12th Floor, New York, NY, 10036, US

(73) Assignee: Printar Ltd.

(21) Appl. No.: 11/907,346

(22) Filed: Oct. 11, 2007

(51) Int. Cl. B41L 13/12; H05K 3/00

(52) U.S. Cl. 101/126; 101/129; 29/846

(57) ABSTRACT

An apparatus for printing PCBs includes both solder mask ink and notation ink printing subsystems within the same unit. Notation ink and solder mask ink may be applied by a single apparatus or by separate apparatuses, such as an ink jet printer, and may be dried by a single drying mechanism or by separate drying mechanisms. The apparatus may also be equipped with a flipping station to allow dual-sided printing and/or a curing station to complete the PCB printing process.

The present invention relates to an apparatus combining various elements in the PCB finishing processes and a method for combining steps in the digital manufacturing of printed circuit boards (PCB) using inkjet printers.

### BACKGROUND OF THE INVENTION

The printed circuit board (PCB) or printed wiring board (PWB) is the platform that connects and interfaces most electronic components with each other and with other elements in computers, communication devices, consumer electronics, automated manufacturing and inspection equipment. The procedures of manufacturing these circuit boards and of inserting and connecting multiple components, such as resistors, capacitors and integrated circuits, can be applied in mass production environments, achieving substantial automation, which results in costs reduction, high reliability and high component packaging densities. Backplanes and panels (interconnecting boards, in which printed circuits, panels or integrated circuit packages can be plugged or mounted into or onto) are also manufactured in a similar manner. Modem, highly-dense, populated boards require sophisticated and high resolution manufacturing techniques with precise registration capabilities.

A PCB is produced from a base of insulating material on which a thin copper layer is laminated or plated, known as a bare copper plated board, from which a chemical etching step selectively removes areas of the copper to produce electrically conducting paths. This selective removal is achieved by covering the copper layer with a patterned mask (etch-resist) that protects the copper layer in the following etching step. For simpler PCBs, screen-printing techniques are generally utilized to form the patterned mask, and for more densely populated PCBs having generally complicated multi-layer conducting paths, Liquid Photo Imageable etch and solder resist mask procedures are commonly utilized. The pattern that remains on the board after the etching step is commonly known as the primary image conductor pattern.

The components leads must then be connected to predetermined positions in the conducting paths (called pads) by soldering the leads and the conducting paths utilizing a molten metal alloy, which, after solidifying, achieves a permanent electrically conductive bond. In mass production, wave-soldering methods are commonly utilized, wherein the PCB passes through a molten solder wave that coats the pads and leads and thus forms the required solder joints. A solder resist mask protects the conducting paths from being coated with solder during the soldering step. The solder resist mask leaves uncovered only the pads that need to be covered by the molten solder; otherwise, the conducting paths would also be covered with solder, causing several problems such as short circuits by bridging solder.

Various finishing processes in the manufacturing of PCBs currently use (or will be able to use shortly) state of the art inkjet printers. These printers are used to deposit specific kinds of material on the surface of the PCB according to computer generated graphics.

In one application, an inkjet printer may be used to cover the PCB with a material that acts as a solder mask in the ensuing manufacturing processes and acts as a protective cover layer throughout the life of the finished electronics subsystem. This solder mask may be applied using any conventional method such as “curtain coating” and “silkscreen” methods. The solder mask coating may also be applied digitally, as described, for example, in U.S. Patent Application Publication No. 2005/0176177 (Zohar et al.) and International Patent Application Publication No. WO 03/075623 (Zohar et al.), the disclosures of which are incorporated herein in their entireties, and which disclose a method and apparatus for applying ink, according to a solder mask pattern, to a printed circuit board having elevated pads defining pad edges. The method includes flooding the printed circuit board with ink such that the ink advances to the pad edges and is stopped thereby and thereat, without climbing onto the elevated pads.

In another application, inkjet printers deposit notation ink (normally white in color) to print human or machine readable information such as legend, 1D or 2D Barcode, geometry defining lines, etc. See, for example, U.S. Pat. No. 6,754,551 (Zohar et al.), the disclosure of which is incorporated herein in its entirety, and which describes a jet dispensing print system for dispensing a liquid or viscous substance as a pattern onto the surface of a PCB in an industrial manufacturing PCB production line. The system includes a printing system having a printing bridge system that includes a static and rigid printing bridge to accommodate in a precise manner several jet print heads, a printing table positioned underneath the static and rigid printing bridge, a motorized system for moving the printing table simultaneously in two perpendicular directions while the pattern is dispensed in a jetting maimer onto the PCB, a control system, and a user interface. The jet dispensing PCB print system may be utilized for, inter alia, legend print, solder mask, etch resist mask, plating resist, temporary (peelable) mask, adhesives, CSP and bare die encapsulation.

Currently, each application must be performed by a separate ink jet printer machine performing only one of the tasks at each step. This is because the material deposition process and steps for solder masks and printed legends require different materials that behave differently due to their differing chemical characteristics. Specifically, a first ink jet printer apparatus applies the solder mask, followed by a lengthy curing period. Then, another ink jet printer apparatus performs the printing function, followed by another lengthy curing period. It has heretofore been unknown and believed to be impossible to combine of more than one material deposition process together into a single machine using inkjet technology.

However, the use of separate machines and manufacturing steps results in various inefficiencies, such as time delay, material logistics, storage, manual or automatic load/unload and other costly handling processes. In addition, serial processes with multiple handling at each stage increases the chances for contamination and errors.

### SUMMARY OF THE INVENTION

It is one object of the present invention to provide a system wherein solder masks and printed legends can be applied to a PCB contemporaneously and using the same apparatus.

Another object of the present invention is to combine two or more material deposition processes and steps into a single machine using inkjet technology.

In accordance with these and other objects of the invention, the deposition of Solder Mask and the deposition of notation ink are combined within a single machine performing both processes. The combination of these two steps reduces board handling and improves accuracy of deposition as well as reliability. Curing can be combined for the two steps and be performed at once, thus saving valuable time.

In one embodiment, the invention comprises a common PCB handling system, two separate printing and ink supply systems, and one common ink drying subsystem.

In another embodiment, the invention comprises two separate PCB handling, printing and drying stations combined with automation moving the PCB inside the machine from one station to the other.

Further embodiments of the invention comprise either of the above configurations followed by a curing substation. Still further embodiments of the invention comprise either of the above embodiments and a flipping station for 2-sided printing. Even further embodiments of the invention comprise either of the above embodiments and a loading/unloading station.

One point of innovation in this invention is in the combination of more than one of the material deposition processes and steps into a single machine using inkjet technology.

The materials supply, printing subsystems and drying mechanisms need not be identical. The materials may vary in their printing and/or drying characteristics (such as UV or thermal). The printing resolution need not be identical. The thickness of the deposited material need not be identical.

The machine is seen by the user as a single machine performing the complete “finishing” process. The human interface may enable programming of the machine as a single task or as two separate tasks each with individual characteristics.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may be best understood by reference to the following detailed description when read with the accompanied drawings in which:

FIG. 1 is a general block diagram of the various components in accordance with one embodiment of the present invention.

FIG. 2 is a general block diagram of the various components in accordance with a second embodiment of the present invention.

FIG. 3 is a general block diagram of the various components in accordance with a third embodiment of the present invention.

FIG. 4 is a general block diagram of the various components and process flow of a fourth embodiment of the present invention.

### DETAILED DESCRIPTION OF THE INVENTION

In the following detailed description, numerous specific details are set forth in order to provide a thorough understanding of the invention. For convenience of explanation, the invention is described below with reference to preferred embodiments, which comprise a legend printing and a solder mask printing system. However, it will be understood by those of ordinary skill in the art that the present invention may be practiced without these specific details. For example, those versed in the art will readily appreciate that the invention is by no means bound to these embodiments and various dispensing methods for, inter alia, primary image conducting patterns, etch resist mask patterns, temporary masks, edging non-uniformity compensation control masks, selective conformal coatings, chip-on-board encapsulation, liquid encapsulates, bar codes, and adhesives in surface mount technology (SMT), are within the scope of the present invention. Furthermore, applying certain minor modifications, the present invention is equally suitable for SMT solder paste printing applications. In other instances, well-known methods, procedures, components and circuits have not been described in detail so as not to obscure the present invention.

With reference to FIG. 1, apparatus 100 is a first embodiment of the present invention. Loading/unloading mechanism 101 is the primary mechanism through which PCBs enter or exit apparatus 100. Loading/unloading mechanism 101 may employ any technique known the mass production arts including, but not limited to, conveyer belts, slot loading mechanisms, magazine-loading mechanisms, vertical buffering, manual placement, etc. Either PCBs may be manually inserted into and removed from apparatus 100, or the loading/unloading process may be automated to convey PCBs from previous and/or subsequent steps in the PCB manufacturing process.

Once the PCB is loaded into apparatus 100, the position, orientation and movement of the PCB within apparatus 100 is controlled by PCB Handling mechanism 102. In the embodiment shown in FIG. 1, PCB Handling mechanism 102 moves PCBs among Solder Mask Printing Subsystem 103, Legend Printing Subsystem 104, and Drying Mechanism 105.

It is understood that PCB Handling mechanism 102 may employ techniques such as conveyor belts, servo motors or any other technique known in the art of PCB manufacturing. Accuracy of PCB placement may be confirmed by computer controlled optical cameras, using computer vision techniques known in the mass production arts. PCB Handling mechanism 102 may also include a vacuum based handling apparatus, similar to that employed in wafer processing, in which the underside of the PCB is held in place by a vacuum seal to minimize PCB movement and enhance precision printing. PCB clamps, which are brought to position either manually or automatically, may be used either in conjunction with the vacuum based handling apparatus, or by itself. Alternatively, PCB Handling mechanism 102 may be designed not to move PCBs between various internal components of apparatus 100, but rather to hold the PCB stationary while the various printer subsystems move themselves relative to the PCB. PCB Handling Mechanism 102 may also be equipped with a debris cleaning system, employing a turbofan, particle collection trap, vacuums and/or a series of brushes.

Solder Mask Printing Subsystem 103 and Legend Printing Subsystem 104 may employ any known means of applying solder mask, including but not limited to using ink jet printing units, applying the solder mask material and legend ink directly through a predefined stencil (screen printing), or coating with photoimageable materials and exposing to light either directly (laser direct imaging) or indirectly via a photo-tool (contact printing) and then developing.

In a preferred embodiment, Solder Mask Printing Subsystem 103 employs a number of jet heads fitted with a multitude of jet nozzles, in a manner similar to that used in consumer inkjet printers. Some of these jet nozzles may be employed as backup nozzles, to achieve fault-tolerating redundancy. An ink supply system may feed the jet heads with solder mask ink according to known techniques in the inkjet printing art. Solder Mask Printing Subsystem 103 may also employ a computer to control the dispensing of the pattern onto the PCB by the jet heads. It is to be understood that while PCB handling mechanism 102 may comprise a printing table capable of moving a PCB along at least two perpendicular directions, the PCB may actually be held static and the jet heads of Solder Mask Printing Subsystem 103 move relative to the PCB. For an extended discussion of solder mask inkjet printing, see U.S. Pat. No. 6,754,551 to Zohar et al., referred to hereinabove.

In a preferred embodiment, Legend Printing Subsystem 104 employs a jet head configuration similar to that of Solder Mask Printing Subsystem 103 to deposit notation ink onto the PCB. The number of jet heads in Legend Printing Subsystem 104, and consequently the resolution, need not be the same as that of Solder Mask Printing Subsystem 103. Similarly, the thickness of the deposited material may vary.

PCB Handling mechanism 102 may be employed to move the PCB between the Legend Printing Subsystem 104 and Solder Mask Printing Subsystem 103. Preferably, Solder Mask Printing Subsystem 103 and Legend Printing Subsystem 104 would employ jet heads mounted sufficiently close to each other such that a PCB would not have to be moved from one subsystem to another. In such a configuration, solder mask ink and legend printing ink could be deposited onto a PCB either simultaneously, serially, or in an alternating fashion, depending on the complexity of the pattern to be printed. In either case, both solder mask ink and notation ink can be deposited onto a PCB far more quickly and efficiently than by methods found in the prior art. However, printing and drying the solder mask ink before printing notation ink is a preferred embodiment.

Alternatively, Legend Printing Subsystem 104 and Solder Mask Printing Subsystem 103 may use the same jet head, depending on the physical characteristics of the solder mask and legend inks and the efficiency concerns of the PCB mass production process. However, in such a configuration, an intermediate purging/cleaning step may be required in order to change printing inks between Solder Mask printing and Legend Ink printing.

In the embodiment of this invention depicted in FIG. 1, after each of the solder mask ink and the notation ink have been deposited by Solder Mask Printing Subsystem 103 and by Legend Printing Subsystem 104, respectively, Drying Mechanism 105 receives the PCB and performs the drying step. As explained above, PCB Handling mechanism 102 coordinates PCB placement, movement, and orientation within apparatus 100, and prepares the PCB for the drying process, which may not require substantial movement of the PCB following any of the preceding steps in the inkjet printing process. Drying Mechanism 105 may employ either thermal or UV ink drying techniques, or both, as is well known in the inkjet printing art, depending upon the needs and characteristics of the solder mask and notation ink. Both thermal and UV drying techniques may also be employed simultaneously or sequentially, thereby saving considerable time and expense of having multiple drying subsystems corresponding to the various ink types employed by the apparatus. Other embodiments of the Drying Mechanism 105 may allow concurrency in the drying process. For instance, one might coat the PCBs with solder mask and legend materials that could be sensitive to different wavelengths, expose solder mask with one wavelength and legend with another wavelength.

A PCB printing process employing apparatus 100 in FIG. 1 may be performed as follows: after being loaded into apparatus 100 by means of Loading/Unloading mechanism 101, the PCB is positioned by PCB Handling mechanism 102 to engage with Solder Mask Printing Subsystem 103 and Legend Printing Subsystem 104, in any order, with an optional intermediate drying step between the solder ink printing step and the notation ink printing step. After engaging both Solder Mask Printing Subsystem 103 and Legend Printing Subsystem 104, PCB Handling mechanism 102 positions the PCB to engage with Drying Mechanism 105 for a final drying step before unloading the PCB through Loading/Unloading mechanism 101. The entire process, including any handling between steps, is computer controlled by customizable software, using techniques known in the mass production arts.

All of the above cited elements comprising apparatus 100 are enclosed within a housing (not shown) of a type commonly employed in the mass production arts, preferably designed to minimize the space required and promote the efficient handling of PCBs. In certain embodiments, Loading/unloading mechanism 101 may not be considered to be enclosed within the housing.

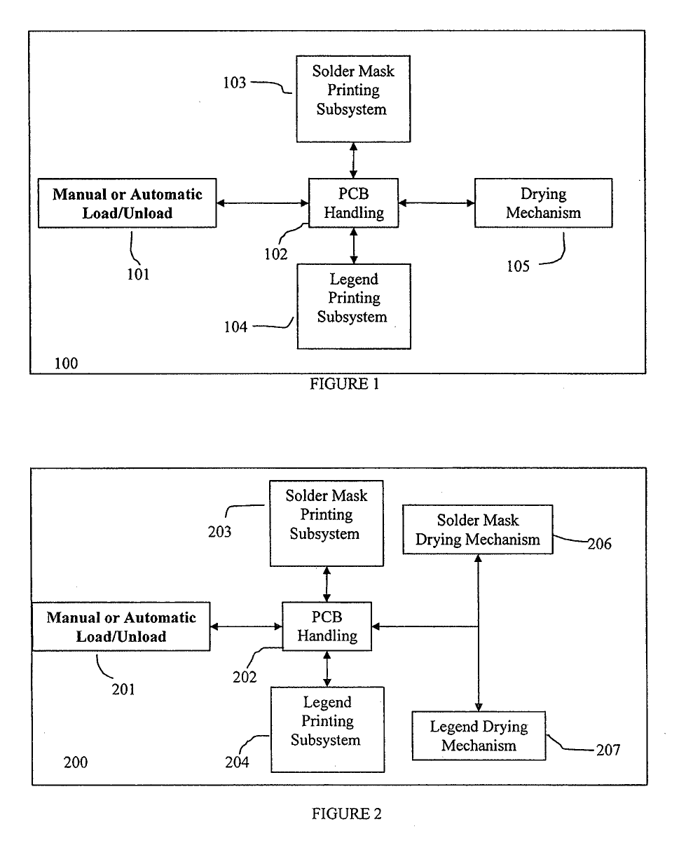

Referring to FIG. 2, apparatus 200 is a variation of apparatus 100, but in which separate drying mechanisms 206 and 207 are employed to dry both solder mask ink and notation ink, respectively. This configuration may provide easier upgradeability for damaged or outdated drying mechanisms, and may prove less costly than employing an integrated drying unit for both solder ink and notation ink. Separate drying mechanisms also allow for individualized characteristics for each drying step, such as UV or thermal drying, as well as individualized temperature and duration settings.

A PCB printing process employing apparatus 200 in FIG. 2 may be performed as follows: after being loaded into apparatus 200 by means of Loading/Unloading mechanism 201, the PCB is positioned by PCB Handling mechanism 202 to engage with Solder Mask Printing Subsystem 203 and Legend Printing Subsystem 204. Each printing step is followed by a drying step in that subsystem's dedicated drying mechanism. After engaging both Solder Mask Printing Subsystem 203 and Legend Printing Subsystem 204, and their respective drying mechanisms 206 and 207, PCB Handling mechanism 202 unloads the PCB through Loading/Unloading mechanism 201. The entire process, including any handling between steps, is computer controlled by customizable software, using techniques known in the mass production arts.

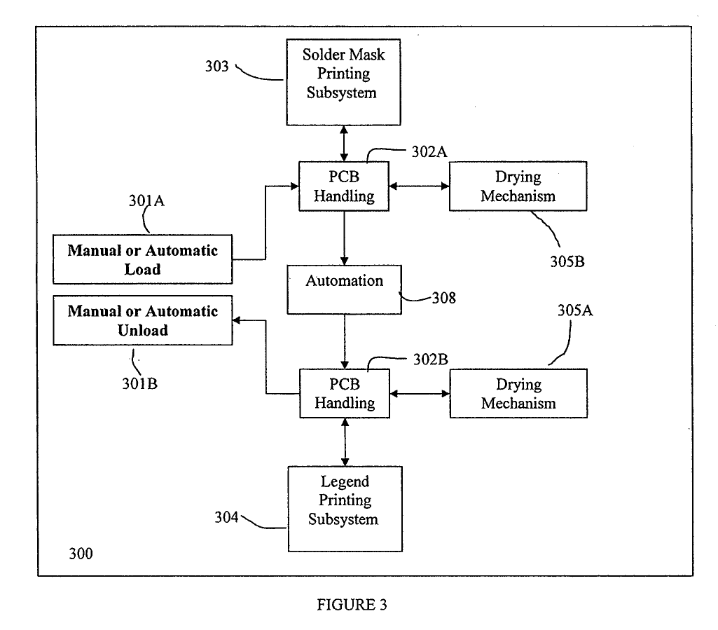

FIG. 3 depicts apparatus 300, which is a further modification of apparatus 100 and 200, as depicted in FIG. 1 and FIG. 2 respectively, but which employs two separate PCB Handling mechanisms 302A and 302B and two separate Drying Mechanisms 305A and 305B. In addition, discrete loading and unloading mechanisms have been employed as 301A and 301B, respectively. This configuration allows for two PCBs to be imprinted simultaneously by both Solder Mask Printing Subsystem 303 and Legend Printing Subsystem 304 at two separate stations. Both Solder Mask Printing Subsystem 303 and Legend Printing Subsystem 304 may each employ a dedicated Drying Mechanism 305, similar to those discussed above in connection with FIG. 2. Automation 308 uses standard mass production techniques to transfer PCBs between both stations, such as conveyer-belts, automatic magazine loading, etc.

A PCB printing process employing apparatus 300 in FIG. 3 may be performed as follows: after being loaded into apparatus 300 by means of Loading mechanism 301A, the PCB is positioned by PCB Handling mechanism 302A to engage with Solder Mask Printing Subsystem 303, followed by a drying step in Drying Mechanism 305A. PCB Handling mechanism 302A then transfers the PCB to PCB Handling mechanism 302B by means of Automation 308. At this new station, the PCB then engages with Legend Printing Subsystem 304, followed by a second drying step in Drying Mechanism 305B. PCB Handling mechanism 302B then unloads the PCB from apparatus 300 by means of Unloading mechanism 301B. The entire process, including any handling between steps, is computer controlled by customizable software, using techniques known in the mass production arts.

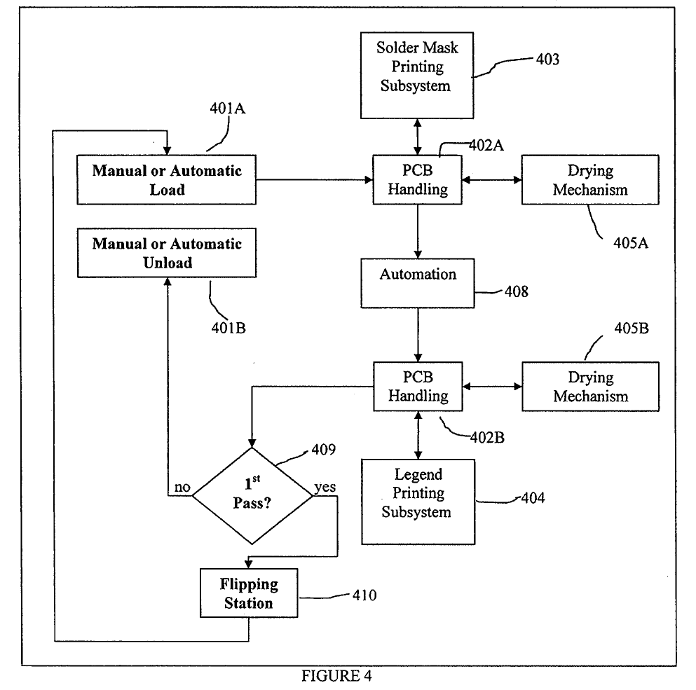

Apparatus 400 in FIG. 4 is a variation of FIG. 3, which provides for double-sided printing of PCBs. After a PCB has been processed by both Solder Mask Printing Subsystem 403 and Legend Printing Subsystem 404, and their respective Drying Mechanisms 405A and 405B, first pass detector 409 determines whether or not this is this is the “first pass” of the PCB processing, i.e., whether additional printing on the opposite side of the PCB is required. If so, the PCB is passed to Flipping Station 410, which flips the PCB and feeds it back into loading mechanism 401A for further printing by Solder Mask Printing Subsystem 403 and/or Legend Printing Subsystem 404. If no further printing is required, the PCB is passed to unloading mechanism 401B. First pass detector 409 may be implemented as logic embedded in hardware, or may be incorporated into software which controls various other aspects of this invention.

It is to be understood that double sided printing may be similarly added to the either of the apparatuses embodied in FIG. 1 and FIG. 2, and is not limited to the embodiment described in FIG. 4.

A PCB printing process employing apparatus 400 in FIG. 4 may be performed as follows: after being loaded into apparatus 400 by means of Loading mechanism 401A, the PCB is positioned by PCB Handling mechanism 402A to engage with Solder Mask Printing Subsystem 403, followed by a drying step in Drying Mechanism 405A. PCB Handling mechanism 402A then transfers the PCB to PCB Handling mechanism 402B by means of Automation 408. At this new station, the PCB then engages with Legend Printing Subsystem 404 followed by a second drying step in Drying Mechanism 405B. First Pass Detector 409 then determines whether the other side of the PCB requires printing by one or both printing subsystems. If printing on the reverse side of the PCB is required, PCB Handling mechanism 402B transfers the PCB to Flipping Station 410, where the PCB is flipped and fed back to Loading mechanism 401A. If no further printing is required, PCB Handling mechanism 402B then unloads the PCB from apparatus 400 by means of Unloading mechanism 401B. The solder mask ink printing and legend ink printing steps may be swapped if necessary or desired. The entire process, including any handling between steps, is computer controlled by customizable software, using techniques known in the mass production arts.

Each of the above apparatus embodiments may be combined with a curing station to complete the PCB printing process. The curing station, as is well known in the art, hardens the solder mask applied to the PCB, and can employ standard curing techniques, such as thermal curing. In certain types of printing, such as screen printing and coating with photo-imageable materials and exposing to light either directly or indirectly via a photo-tool, some sort of finishing (developing, partial or complete curing etc.) is necessary, particularly after printing of the solder mask and before legend ink can be applied.

The present invention has been described with certain degree of particularity. Those versed in the art will readily appreciate that various modifications and alterations may be carried out without departing from the scope of the following claims:

1. An apparatus for printing printed circuit boards (PCBs) comprising:
a solder mask printing susbystem;
a legend printing susbystem;
at least one drying mechanism;
a PCB handling mechanism for handling the position, orientation, and movement of PCBs within said apparatus; and
a housing enclosing at least said solder mask printing susbystem, said legend printing susbystem, said at least one drying mechanism and said handling mechanism.

2. The apparatus of claim 1, wherein said apparatus has exactly one drying mechanism capable of drying both solder mask and legend ink.

3. The apparatus of claim 1, further comprising a first pass detector for determining whether additional printing on the reverse side of a PCB is required, and a flipping station capable of flipping a PCB in response to said first pass detector.

4. The apparatus of claim 1, further comprising a drying mechanism for drying the solder mask ink.

5. The apparatus of claim 1, wherein either or both of said solder mask printing susbystem and said legend printing susbystem are inkjet printers.

6. The apparatus of claim 1, wherein said solder mask printing susbystem and said legend printing susbystem are capable of motion relative to a PCB.

7. The apparatus of claim 1, further comprising a mechanism for loading and unloading PCBs.

8. An apparatus for printing printed circuit boards (PCBs) comprising:
solder mask printing susbystem;
legend printing susbystem;
a first drying mechanism for drying solder mask ink;
a second drying mechanism for drying legend ink;
a mechanism for handling the position, orientation, and movement of PCBs within said apparatus, and from said first printing station to a second printing station; and
a housing enclosing at least said solder mask printing susbystem, said legend printing susbystem, said first and second drying mechanisms and said handling mechanism.

9. The apparatus of claim 8, further comprising a first pass detector for determining whether additional printing on the reverse side of a PCB is required, and a flipping station capable of flipping a PCB in response to said first pass detector.

10. The apparatus of claim 8, further comprising a drying mechanism for drying the solder mask ink.

11. The apparatus of claim 8, wherein either or both of said solder mask printing susbystem and said legend printing susbystem are inkjet printers.

12. The apparatus of claim 8, wherein said solder mask printing susbystem and said legend printing subsystem are capable of motion relative to a PCB.

13. The apparatus of claim 8, further comprising a mechanism for loading PCBs into said solder mask printing subsystem or said legend printing subsystem.

14. The apparatus of claim 13, further comprising a mechanism for unloading PCBs from said solder mask printing subsystem or said legend printing subsystem.

15. A method for printing solder mask and legend ink on printed circuit boards (PCBs) comprising:
loading a PCB into a housing enclosing at least a solder mask printing subsystem, a legend printing subsystem and at least one drying mechanism,
applying solder mask using said solder mask printing subsystem;
applying legend ink using said legend printing subsystem;
drying said PCB using said drying mechanism; and
unloading said PCB from said housing.

16. The method of claim 15, wherein said housing encloses exactly one drying mechanism capable of drying both solder mask and legend ink.

17. The method of claim 15, wherein said housing encloses a first drying mechanism for drying solder mask ink and a second drying mechanism for drying legend ink, and said step of drying said PCB comprises a first step of drying said solder mask ink and a second step of drying said legend ink.

18. The method of claim 15, wherein said housing further encloses a first pass detector for determining whether additional printing on the reverse side of said PCB is required and a flipping station capable of flipping said PCB in response to said first pass detector,
said method further comprising the steps of determining whether additional printing on the reverse side of said PCB is required and flipping said PCB in response to said determining step.

19. The method of claim 15, wherein either or both of said steps of applying solder mask ink and legend ink are performed though inkjet printing.

20. The method of claim 15, wherein said housing further encloses a drying mechanism for drying the solder mask ink, said method further comprising the step of drying said PCB.
